(19) United States
(12) Patent Application Publication
(10) Pub. No.: US 2013/0286605 A1
(43) Pub. Date: Oct. 31, 2013

(54) ELECTRONIC DEVICE COMPRISING SIGNAL RECEIVING UNIT

(71) Applicant: HONG LI, Shenzhen City (CN)

(72) Inventor: HONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/594,858

(22) Filed: Aug. 26, 2012

(30) Foreign Application Priority Data
Apr. 26, 2012 (CN) 201210125612.4

(51) Int. Cl. H05K 7/02

(52) U.S. Cl. 361/752

(57) ABSTRACT

An electronic device includes a housing having a bottom wall and a front sidewall slantingly extending from the bottom wall, a circuit board received in the housing and parallel to the bottom wall, a sensor window cover secured to the front sidewall, a signal receiving unit secured to the circuit board and corresponding to the sensor window cover, and a supporting mechanism secured to the circuit board. The supporting mechanism supports the signal receiving unit to slant toward the sensor window cover.

### BACKGROUND

1. Technical Field

The present disclosure relates to electronic devices, and particularly to an electronic device comprising a signal receiving unit.

2. Description of Related Art

Electronic devices, such as DVD players, may include a housing having a bottom plate and a front sidewall slantingly extending from a rim of the bottom wall, a sensor window cover secured to the front sidewall, a circuit board received in the housing and parallel to the bottom wall, and a signal receiving unit perpendicularly secured to the circuit board and corresponding to the sensor window. However, the sensor window cover is generally coplanar with front sidewall and is slanted relative to the bottom plate. When the signal receiving unit is perpendicularly secured to the circuit board, the signal receiving unit may maintain a greater distance with the sensor window cover, which may result in a weaker receiving capability of the signal receiving unit.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the four views.

FIG. 1 is a partial perspective view of an electronic device having a supporting mechanism in accordance with an embodiment.

FIG. 2 is a partially disassembled view of the electronic device of FIG. 1.

FIG. 3 is an enlarged view of the supporting mechanism in FIG. 1.

FIG. 4 is a cross-sectional view taken along line IV-IV of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

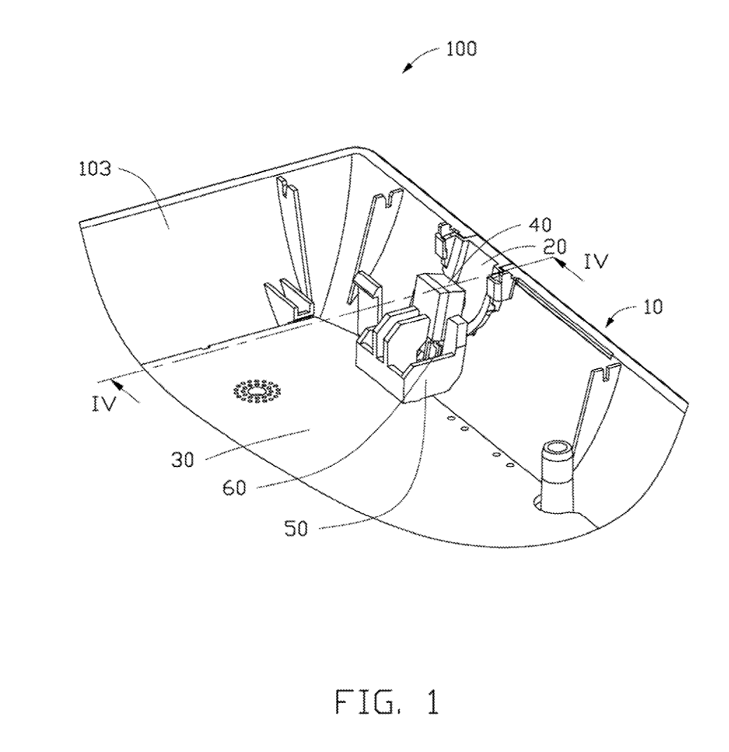

Referring to FIG. 1, an electronic device 100 includes a housing 10, a sensor window cover 20 secured to the housing 10, a circuit board 30 received in the housing 10, a signal receiving unit 40 arranged on the circuit board 30 and corresponding to the sensor window cover 20, and a supporting mechanism 50 secured to circuit board 30. The supporting mechanism 50 supports the signal receiving unit 40 to slant toward the sensor window cover 20.

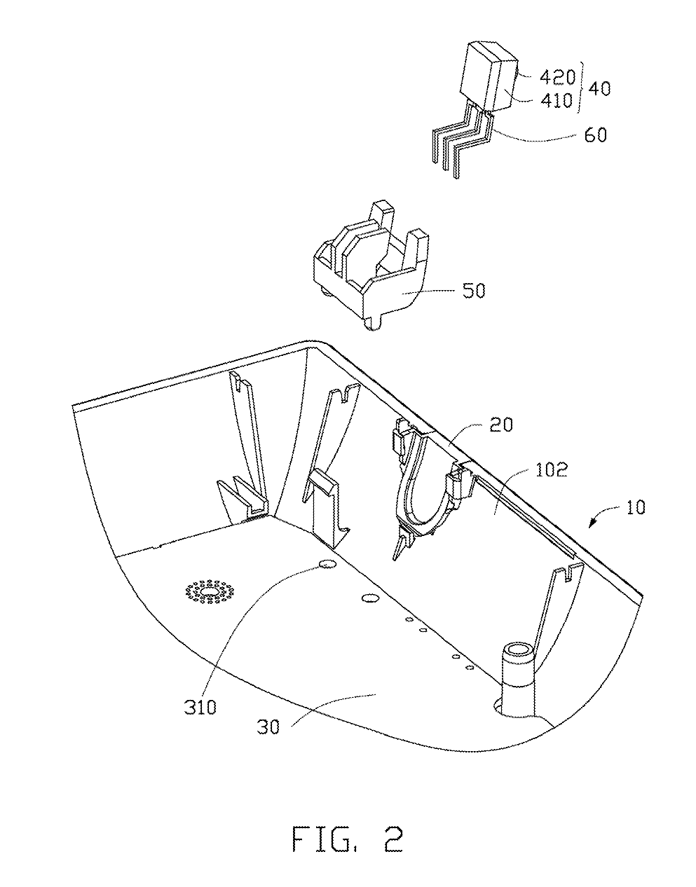

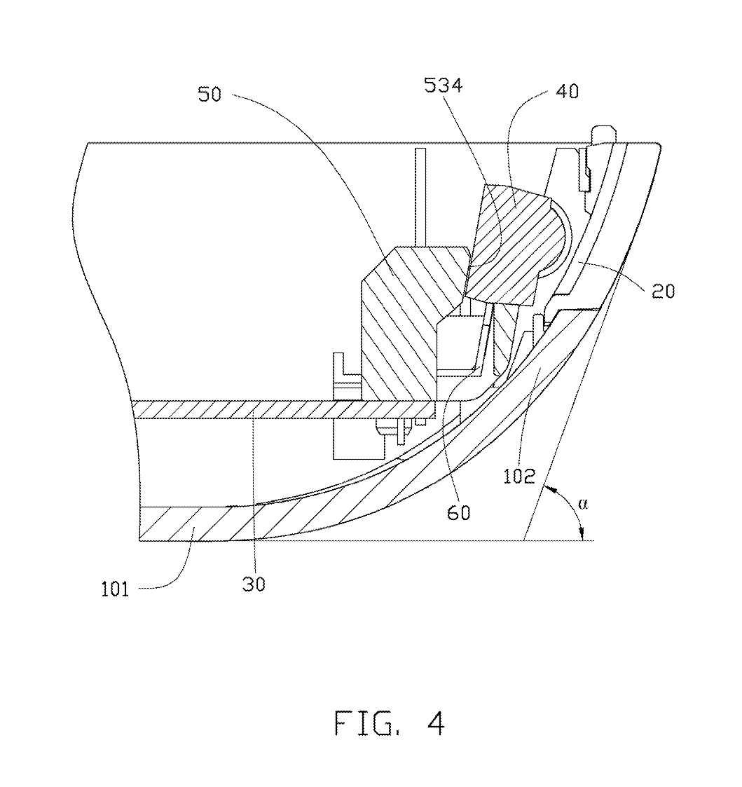

Referring also to FIG. 2, the housing 10 includes a bottom case 110 and a top case (not shown). The bottom case 110 engages with the top case to define a receiving space 103 (FIG. 1) for receiving the circuit board 30, the signal receiving unit 40, the supporting mechanism 50, and other electronic components (not shown) of the electronic device 100. The bottom case 110 includes a bottom wall 101 and a plurality of sidewalls protruding from the rims of the bottom wall 110. One of the sidewalls (referred herein as the front sidewall 102) slantingly extends from a rim of the bottom wall 101 and maintains an angle α (see FIG. 4) with the bottom wall 101. In the embodiment, the angle α is in a range of 0-90 degrees.

The sensor window cover 20 is secured to the front sidewall 102 and maintains the angle α with the bottom wall 101. In the embodiment, the sensor window cover 20 is made of polymethyl methacrylate, and is coplanar with the front sidewall 102.

The circuit board 30 is substantially rectangular, and is arranged parallel to the bottom wall 110. The circuit board 30 defines two fixing holes 310. The fixing holes 310 are arranged at an end of the circuit board 30 adjacent to the front sidewall 102 and correspond to the signal receiving unit 20.

The signal receiving unit 40 is secured to an end of the circuit board 30 adjacent to the front sidewall 102 and corresponds to the sensor window cover 20. The signal receiving unit 40 is electrically connected to the circuit board by a plurality of pins 60. In the embodiment, the pins 60 is conductive and is stiff enough to support the signal receiving unit 40 in the circuit board 30. The signal receiving unit 40 includes a main body 410 and a receiving portion 420 secured to the main body 410. The receiving portion 420 is substantially semispherical and corresponds to the sensor window cover 20.

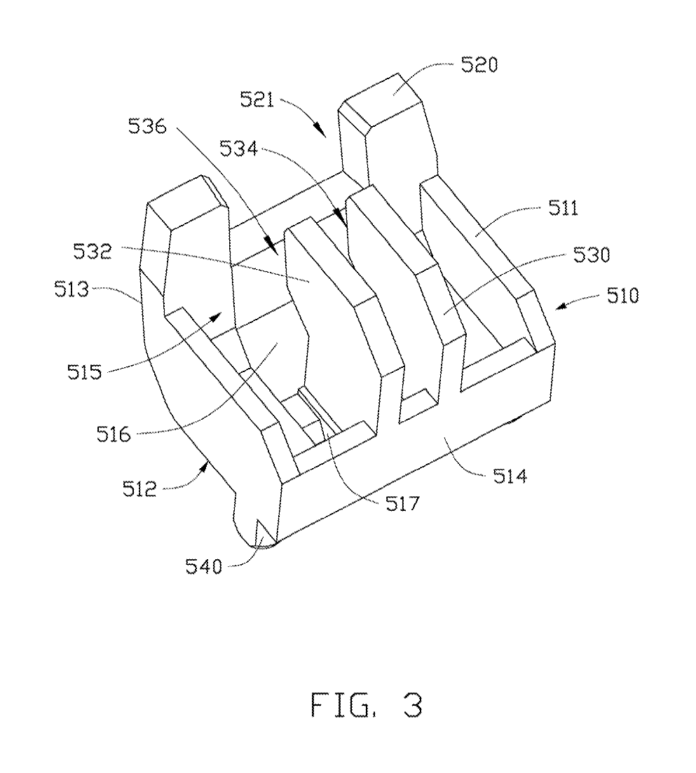

Referring to FIG. 3, the supporting mechanism 50 is secured to the circuit board 30 and is used to support the signal receiving unit 40 to slant toward the sensor window cover 20. In the embodiment, the supporting mechanism 50 supports the signal receiving unit 40 to maintain the angle α with the bottom wall 101, such that the receiving unit 40 is substantially parallel to the front sidewall 102.

The supporting mechanism 50 includes a base 510, a holding member 520 protruding from an end of the base 510 adjacent to the sensor window cover 20, two abutting members 530 secured to the base 510 and parallel with each other, and two fixing posts 540 secured to a surface of the base 510 opposite to the holding member 520.

The base 510 includes a top surface 511, a bottom surface 512 opposite to the top surface 511, a front end 513, and a rear end 514 opposite to the front end 513. The top surface 511 define a receiving groove 515. The bottom of the receiving groove 515 defines three through holes 517. The through holes 517 are spaced from each other and are aligned parallel to and adjacent to the rear end 514. The bottom of the receiving groove 515 further defines an opening 516. The opening 516 is arranged adjacent to the front end 513.

An end of the holding member 520 away from the top surface 511 define a recess 521 for receiving the main body 410 of the signal receiving unit 40. Each abutting member 530 perpendicularly extends from the bottom of the receiving groove 515 and perpendicularly connects with the rear end 514. Each abutting member 530 is arranged between two adjacent through holes 517. An end of each abutting member 530 bents toward the holding member 520 to from a cantilever 532. The projection of the cantilevers 532 to the bottom of the receiving groove 515 extend into the opening 516. Each cantilever 532 defines an abutting surface 534. The abutting surface 534 extends in a direction parallel to the front sidewall 102. In the embodiment, when the supporting mechanism 50 is secured to the circuit board 30, the abutting surface 534 maintains the angle α with the bottom wall 101. The abutting surface 534 cooperates with the recess 521 of the holding member 520 to define a holding space 536 communicating the opening 516. The fixing posts 540 protrude from the rear surface 512 and are arranged adjacent to the rear end 514. The fixing posts 540 correspond to and are received in the fixing holes 310 respectively.

Referring to FIG. 4, in assembly, first, the supporting mechanism 50 is secured to the circuit board 30 by the fixing posts 540 being received in the corresponding fixing holes 310, with the holding member 520 facing the sensor window cover 20. Second, ends of the pins 60 extend through the through holes 517 and are further electrically fixed to the circuit board 30. Finally, the main body 410 of the signal receiving unit 40 is electrically connected to ends of the pins 60 away from the circuit board 30 and is further clipped in the holding space 536 with an end of the main body 410 opposite to the receiving portion 420 being abutted by the abutting surface 534. Because the abutting surface 534 extends in a direction parallel to the front sidewall 102, the signal receiving unit 40 is supported to slant toward the sensor window cover 20 by the supporting mechanism 50. As a result, the signal receiving unit 40 can receives signals better.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing having a bottom wall and a front sidewall slantingly extending from the bottom wall;
a circuit board received in the housing and parallel to the bottom wall;
a sensor window cover secured to the front sidewall;
a signal receiving unit secured to the circuit board and corresponding to the sensor window cover; and
a supporting mechanism secured to the circuit board;
wherein the supporting mechanism supports the signal receiving unit to slant toward the sensor window cover.

2. The electronic device of claim 1, wherein the front sidewall maintains an angle α with the bottom wall.

3. The electronic device of claim 2, wherein the sensor window cover is coplanar with the front sidewall and maintains the angle α with the circuit board.

4. The electronic device of claim 3, wherein the supporting mechanism supports the signal receiving unit to be parallel with the front sidewall.

5. The electronic device of claim 1, wherein the supporting mechanism comprises a base and at least one abutting member secured to the base, the at least one abutting member defines an abutting surface extending in a direction parallel to the front sidewall for abutting the signal receiving unit to slant toward the sensor window cover.

6. The electronic device of claim 5, wherein the base defines a receiving groove, the at least one abutting member protrudes from the bottom of the receiving groove and is arranged away from the sensor window cover.

7. The electronic device of claim 6, wherein the bottom of the receiving groove further defines an opening, the opening is arranged adjacent to the sensor window cover, and the projection of the abutting surface to the bottom of the receiving groove extend into the opening.

8. The electronic device of claim 7, wherein the supporting mechanism further comprises a holding member, the holding member is secured to an end of the base adjacent to the sensor window cover.

9. The electronic device of claim 8, wherein the holding member defines a recess for receiving the signal receiving unit.

10. The electronic device of claim 6, wherein the signal receiving unit is electrically connected to the circuit board by a plurality of pins.

11. The electronic device of claim 10, wherein the bottom of the receiving groove defines a plurality of through holes for allowing the pins to extend through the plurality of through holes.

12. The electronic device of claim 10, wherein the pins support the signal receiving unit to the circuit board.
